(19) United States
(12) Patent Application Publication
(10) Pub. No.: US 2016/0049769 A1
(43) Pub. Date: Feb. 18, 2016

(54) METHOD AND APPARATUS FOR IMPLEMENTING TUNABLE LIGHT SOURCE

(71) Applicant: Electronics and Telecommunications Research Institute, Daejeon (KR)

(72) Inventor: Byung Seok CHOI, Daejeon (KR)

(73) Assignee: Electronics and Telecommunications Research Institute, Daejeon (KR)

(21) Appl. No.: 14/548,780

(22) Filed: Nov. 20, 2014

(30) Foreign Application Priority Data
Aug. 12, 2014 (KR) 10-2014-0104382

(51) Int. Cl. H01S 5/14

(52) U.S. Cl. CPC H01S 5/14

(57) ABSTRACT

Provided herein is a method and apparatus for implementing a tunable light source, the method including performing a first calibration of obtaining a tuning curve representing changes of a wavelength as a function of a heater power up to a wavelength range where the external cavity type tunable light source is tunable; performing a second calibration of obtaining a detuning curve of the tunable wavelength range; and setting a wavelength by performing a wavelength locking.

### CROSS-REFERENCE TO RELATED APPLICATION

The present application claims priority to Korean patent application number 10-2014-0104382, filed on Aug. 12, 2014, the entire disclosure of which is incorporated herein in its entirety by reference.

### BACKGROUND

1. Field of Invention

Various embodiments of the present invention relate to optical communication, and more particularly, to a tunable light source for use in optical communication.

2. Description of Related Art

The term ‘LASER’ is an acronym for ‘Light Amplification by Stimulated Emission of Radiation’, and the main element necessary for the formation of a laser is a resonator that includes a gain medium and a pump that supplies energy to the laser. For a radiated light to be amplified by a stimulated emission process, there must be a suitable gain medium the type of which determines the oscillation wavelength band of the laser. The most representative examples of lasers that are relatively easily tunable are gas lasers, dye lasers, and solid-state lasers, according to the types of the gain medium.

Research is actively underway on passive optical networks (PON) that are based on wavelength division multiplexing (WDM) (hereinafter referred to as ‘WDM-PON’). These networks have their basis on adjusting wavelengths. WDM-PON may provide converged services of voice, data, and broadcast.

In WDM-PON, each subscriber communicates with a central office (CO) using a different wavelength assigned to the subscriber. And since each subscriber uses an exclusive wavelength assigned to each subscriber, WDM-PON has excellent security and enables providing massive communication services, and thus it has an advantage that each subscriber or service may be provided with a transmission technology of a different link rate and frame rate.

However, since WDM-PON is a technology of multiplexing various wavelengths in a single optical fiber using the WDM technology, it requires different light sources as many as the number of subscribers that belong to one remote node (RN). Production, installation, and management of light source per wavelength are becoming a great burden to users and subscribers, and thus a big obstacle to commercialization of WDM-PON. In order to resolve such a problem, application methods of tunable light sources capable of selectively tuning the wavelength of a light source is actively being studied.

### SUMMARY

A first purpose of various embodiments of the present invention is to provide a method for implementing a tunable light source.

A second purpose of various embodiments of the present invention is to provide an apparatus for performing a method for implementing a tunable light source.

According to an embodiment of the present invention, there is provided a wavelength controlling method of an external cavity type tunable light source, the method including: performing a first calibration of obtaining a tuning curve representing changes of a wavelength as a function of a heater power up to a wavelength range where the external cavity type tunable light source is tunable; performing a second calibration of obtaining a detuning curve of the tunable wavelength range; and setting a wavelength by performing a wavelength locking. The second calibration may be performed based on phase control power information and heater power information regarding a position where a mode hopping occurs obtained based on the detuning curve. The second calibration may be performed based on a result of a power monitoring, and the power monitoring may be performed by monitoring an output power through a high reflection coated surface of a gain medium. The power monitoring may be performed by further monitoring the output power through the external cavity. The second calibration may be performed based on information on an external temperature where the external cavity type tunable light source operates.

According to an embodiment of the present invention, there is provided an external cavity type tunable light source apparatus including a first calibrator configured to perform a first calibration of obtaining a tuning curve representing changes in a wavelength as a function of a heater power up to a wavelength range where the external cavity type tunable light source is tunable; a second calibrator configured to perform a second calibration of obtaining a detuning curve of the tunable wavelength range; a wavelength locker configured to set a wavelength by performing a wavelength locking; and a controller configured to control the first calibrator and the second calibrator to perform the first calibration and second calibration, respectively, of the external cavity type tunable light source apparatus, and to control the wavelength locker to set the wavelength. The second calibrator may perform the second calibration based on a result of a power monitoring, and the power monitoring may be performed by monitoring an output power through a high reflection coated surface of a gain medium. The power monitoring may be performed by further monitoring the output power through the external cavity. The second calibrator may perform the second calibration based on information on an external temperature where the external cavity type tunable light source apparatus operates.

As aforementioned, a method and apparatus for implementing a tunable light source according to embodiments of the present invention is provided with a tunable external cavity type laser including a phase controller configured to control a phase such that lasing mode is detuned in a long wavelength region having a wavelength longer than the wavelength where the reflectivity of the external reflector is the greatest and a heater configured to adjust the wavelength. Using a tunable external cavity type laser provides an effect of low chirp characteristics and transmission of signals to tens of km by high speed transmission.

### BRIEF DESCRIPTION OF THE DRAWINGS

The above and other features and advantages of the present invention will become more apparent to those of ordinary skill in the art by describing in detail embodiments with reference to the attached drawings in which:

FIG. 1 is a view illustrating a configuration of a conventional WDM-PON using a broadband light source;

FIG. 2 is a view illustrating a configuration of a conventional WDM-PON using a tunable light source;

FIG. 3 are conceptual views illustrating a structure of an external cavity type tunable light source;

FIG. 4 are graphs illustrating an alignment of modes of an external cavity type tunable light source;

FIG. 5 is a graph illustrating changes of characteristics that occur upon operation of a phase controller in an external cavity type tunable light source according to an embodiment of the present invention;

FIG. 6 is a conceptual view illustrating a first calibration method of a method for setting operations of an external cavity type tunable light source according to an embodiment of the present invention;

FIG. 7 are conceptual views illustrating a method for setting operations of an external cavity type tunable light source according to an embodiment of the present invention;

FIG. 8 are conceptual views illustrating a detuning method that is based on power monitoring according to an embodiment of the present invention;

FIG. 9 is a view illustrating changes in a linewidth enhancement factor depending on detuning according to an embodiment of the present invention;

FIG. 10 are views illustrating changes in a detuning curve that occur upon direct modulation according to an embodiment of the present invention;

FIG. 11 is a view illustrating changes of a detuning state caused by changes in an external environment temperature according to an embodiment of the present invention;

FIG. 12 is a flowchart illustrating a method for controlling operations of an external cavity type tunable light source according to an embodiment of the present invention; and

FIG. 13 is a block diagram illustrating an external cavity type tunable light source according to an embodiment of the present invention.

### DETAILED DESCRIPTION

Hereinafter, embodiments will be described in greater detail with reference to the accompanying drawings. Embodiments are described herein with reference to cross-sectional illustrations that are schematic illustrations of embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but may include deviations in shapes that result, for example, from manufacturing. In the drawings, lengths and sizes of layers and regions may be exaggerated for clarity. Like reference numerals in the drawings denote like elements.

Terms such as ‘first’ and ‘second’ may be used to describe various components, but they should not limit the various components. Those terms are only used for the purpose of differentiating a component from other components. For example, a first component may be referred to as a second component, and a second component may be referred to as a first component and so forth without departing from the spirit and scope of the present invention. Furthermore, ‘and/or’ may include any one of or a combination of the components mentioned.

It is also noted that in this specification, “connected/coupled” refers to one component not only directly coupling another component but also indirectly coupling another component through an intermediate component. On the other hand, “directly connected/directly coupled” refers to one component directly coupling another component without an intermediate component.

Furthermore, a singular form may include a plural from as long as it is not specifically mentioned in a sentence. Furthermore, “include/comprise” or “including/comprising” used in the specification represents that one or more components, steps, operations, and elements exist or are added.

Furthermore, unless defined otherwise, all the terms used in this specification including technical and scientific terms have the same meanings as would be generally understood by those skilled in the related art. The terms defined in generally used dictionaries should be construed as having the same meanings as would be construed in the context of the related art, and unless clearly defined otherwise in this specification, should not be construed as having idealistic or overly formal meanings.

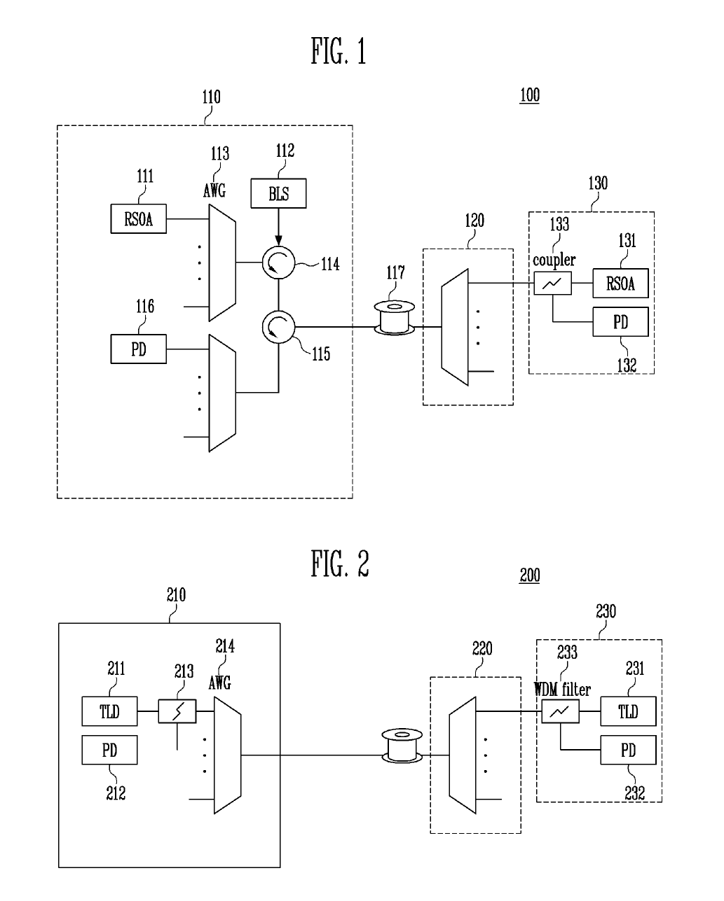

FIG. 1 is a conceptual view illustrating a WDM (wavelength division multiplexing)-PON (passive optical network).

Referring to FIG. 1, a WDM-PON may include an OLT (Optical Line Terminal) 110 that is a placed in a CO (Central office), an ONU or ONT (Optical Network Unit or Optical Network Terminal) 130 that is a subscriber terminal apparatus placed in a subscriber side, and an RN (remote node) 120. The OLT 110 and RN 120 may be connected by a feeder optical fiber 117 of a single core, and the RN 120 and ONU/ONT 130 may be connected by a distribution optical fiber 125.

A downward light to be transmitted from the OLT 110 to the ONU/ONT 130 may be transmitted from a BLS (Broadband Light Source) 112 in the OLT 110 to an RSOA (Reflective Semiconductor Optical Amplifier) 111 for the OLT via a first optical circulator 114 and an AWG (Arrayed Waveguide Grating) 113 that performs WDM multiplexing/demultiplexing functions.

The downward light transmitted to the RSOA 111 may be transmitted from the RSOA 111 for the OLT to the AWG 123 of the RN 120 via the AWG 113, first circulator 114, and second circulator 115, and through the feeder optical fiber 117, and then transmitted to a 1×2 optical coupler (or circulator) 133 in the ONU/ONT 130 through the distribution optical fiber again, and then finally to an RSOA 131 for the ONU and an optical receiver 132.

An upward light to be transmitted from the ONU/ONT 130 to the OLT 110 may be transmitted in a direction opposite to the aforementioned downward light. That is, the upward light may be transmitted from the RSOA 131 for the ONU to an optical receiver 116 for the OLT via the 1×2 RSOA optical coupler 133, distribution optical fiber 125, AWG 123 of the RN 120, feeder optical fiber 117, second circulator 115 and AWG 118.

In the WDM-PON using a broadband light source as illustrated in FIG. 1, the ONU 130 also uses a light source of the OLT 110 side, and thus there is no need to obtain an additional light source in the subscriber terminal. Therefore, it is possible to implement a colorless system. However, since the WDM-PON 100 using a broadband light source injects a seed light source using an additional broadband light source, and the injected seed light source is amplified and modulated in the RSOA 111, there occurs a limitation to the speed, and thus it is regarded that such a WDM-PON 100 is not easy to be used in a 10 Gbps grade system. To compensate this, an element where a reflective electro-absorption modulator is integrated is being proposed as an alternative.

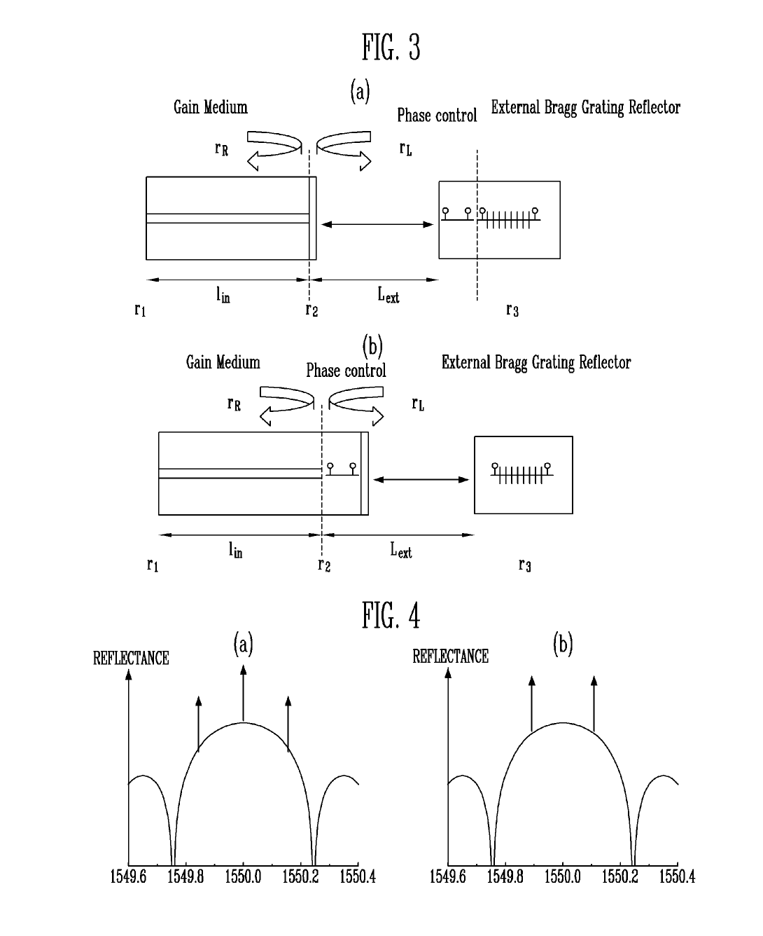

FIG. 2 is a view illustrating a configuration of a conventional WDM-PON using a tunable light source.

Referring to FIG. 2, a WDM-PON includes an OLT 210 placed in a CO (Central office) side, and an ONU/ONT 230 and RN 220 placed in a subscriber side. The OLT 210 and the RN 220 may be connected to each other by an optical fiber 217 of a single core, and the RN 220 and the ONU/ONT 230 may be connected to each other by a distribution optical fiber.

A downward light may be delivered from a TDL (Tunable Laser Diode) 211 to a PD (Photodiode) 232 of the ONU/ONT 230 through a WDM filter 213 and via an AWG 213, feeder optical fiber 217, AWG 223, distribution optical fiber 225, and WDM filter 233. An upward light may proceed in a direction opposite to the downward light, and be transmitted to a PD (Photodiode) 212 of the OLT 210.

Unlike the WDM-PON of FIG. 1, the WDM-PON of FIG. 2 may use tunable light sources 211 and 231 for the OLT 210 and ONU/ONT 230, respectively in order to configure a system that is not dependent on a wavelength. Although the WDM-PON of FIG. 1 that uses a tunable light source has a limitation that the OLT 210 and ONU/ONT 230 must each have a light source, since it is a structure using a laser, it also has an advantage of good performance in terms of speed compared to the WDM-PON of FIG. 1. An important key to implementing such a system lies in whether or not it is possible to make a reliable and high performance tunable light source at low cost.

In an embodiment of the present invention, there is provided a method for implementing a reliable and high performance tunable light source in WDM-PON.

Since an external cavity tunable light source has an effect where an generated light is filtered through the external cavity, single mode lasing becomes much more favorable. However, even if the external cavity laser is under a stable oscillating condition, when there is a change in the current applied or in the external temperature, the lasing mode may move to an region where lasing mode becomes unstable. In such a case, a mode hopping phenomenon to an adjacent mode may occur in the external cavity tunable light source, and sometimes, a multi mode lasing phenomenon may occur. In the case where a phenomenon such as the mode hopping or multi mode lasing occurs, the bit error rate of transmitted data may be increased in optical communication systems using a certain wavelength in a single mode.

Therefore, in using the external cavity tunable light source, determining a stable wavelength region under given conditions or determining a stable operation condition in a given wavelength region is essential.

Hereinafter, explanation on an embodiment of the present invention will be made with the focus on an external cavity tunable light source using a TO (thermo-optic) effect for convenience. However, a method for adjusting a wavelength according to an embodiment may be applied in a same manner to a general external cavity light source and be applied in a suitable manner to individual element methods.

A tunable light source is a core element used in various fields such as spectroscopy and sensor and so forth, and various technologies have been proposed to implement a tunable light source. Major examples of a tunable light source include a single integrated laser that uses a Vernier effect using a semiconductor element including an SG-DBR (Sampled Grating Distributed Bragg Reflector), an external cavity laser using an external grating reflector, and an array laser that implements multi wavelengths by making various single wavelength light sources in an array format.

The tunable technologies used in an external cavity type tunable light source may be classified into a technology that separates wavelengths by diffraction angles using the MEMS (Micro Electro Mechanical System) technology, a technology using the TO (Thermo-Optic) effect, and a technology where a wavelength is tuned by a voltage or current such as liquid crystal and so forth.

Looking at the level of technologies so far, the tunable method by a single integration developed the most, but has a problem of high cost due to the low yield of this type of tunable laser. An array laser also has limitations in application due to its size and yield. In the case of the external cavity laser, the laser may be driven with somewhat stably, but there exist limitations due to the large size and limitations of high speed operations inevitable in an external cavity laser.

FIG. 3 is conceptual views illustrating a structure of an external cavity type tunable light source.

Referring to FIG. 3, the external cavity tunable light source may include a gain medium and external cavity.

The gain medium may be configured to provide a gain necessary to operate a light source.

The external cavity is configured to filter a light generated in the gain medium and to perform a single mode lasing. When such filtering characteristics are tuned according to wavelength, a tunable light source may be implemented. For example, if the external cavity is implemented using a polymer material having a large thermo-optic coefficient, a tunable light source may be formed. For example, if the external cavity is implemented using a polymer material having a large thermo-optical coefficient, a wavelength may be tuned.

The gain medium may be made of a semiconductor material or crystal or gas molecules, and may obtain gain by pumping by an external light or injecting a current. A semiconductor laser may be integrated with a mode converter and so forth to improve optical coupling to the external filter.

The external cavity may be implemented outside the gain medium using a mirror having no wavelength selectivity or Bragg grating reflector having wavelength selectivity.

The external cavity tunable light source may perform a wavelength tuning function based on the external cavity. For example, an external cavity tunable light source may be implemented such that a change occurs in a band where a light generated in a light source passes or is reflected in the light source based on injection of external current, temperature change, or angle adjustment. The external cavity tunable light source may be implemented using a polymer material or semiconductor material and so forth. An external cavity tunable light source may be implemented such that a refractive index may be changed by a plasma effect or thermo-optical effect or that a wavelength is tunable using changes in wavelength caused by changes in a diffraction angle.

In the case of implementing a tunable laser based on the thermo-optical effect of an external cavity tunable light source, an external cavity implemented by forming a Bragg grating may be optical-coupled to a semiconductor gain medium called a superluminescent diode and a polymer material having a large thermo-optical effect.

In an external cavity light source, a heater electrode may be implemented to adjust a wavelength using the thermo-optical effect and adjust the refractive index of an element. A selected wavelength varies due to temperature changes caused by heating of the heater electrode, and thus there is an advantage that the control method for changing a wavelength becomes simple, but since the material itself is an element where the wavelength changes sensitively to temperature, output may easily change due to changes in external environment.

Besides such a gain medium and external cavity, a phase controller may be further provided. The phase controller may be provided separately between the gain medium and the external cavity or integrated into the two components, which causes a subtle change in the optical length of the laser, thus enabling a laser mode to move to a long wavelength or short wavelength.

FIG. 4 is graphs illustrating an alignment of modes of an external cavity type tunable light source. In these graphs, modes of an external cavity tunable light source are expressed as arrows on a reflectivity curve (or if in a transmission type, transmissivity) of an external cavity.

FIG. 4 illustrates two extreme cases: one mode arranged on the peak of a reflection bandwidth or transmission bandwidth; and two modes arranged at the same distance from a peak position. A general lasing mode has a format of something between the two extreme alignment types.

Regarding the alignment of lasing modes as illustrated in FIG. 4(a) with the effect by a nonlinear gain effect excluded, since the mode in the center has the highest reflectivity and thus has the lowest mirror loss, it becomes the lasing mode, while the other modes become side modes. Since there is a big difference of loss between the lasing mode and side modes, when a mode alignment is performed as in FIG. 4(a), output characteristics having a high SMSR (side mode suppression ratio) may be obtained.

In an alignment as illustrated in FIG. 4(b), since there is almost no difference of loss between the two modes, mode hopping may easily occur even by a slight perturbation. Therefore, oscillation characteristics become unstable.

Therefore, to operate this laser with stability, it is important to have a mode alignment as in FIG. 4(a) in an external cavity type tunable light source, thereby stabilizing the modes. However, that is the case when considering only stable operations of an element. When it is important to have low chirp characteristics, it may be necessary to operate the longest wavelength in FIG. 4(a). In either case, in such a mode alignment, it is necessary to decide a reference position and to move a mode to a certain region from the reference position. Hereinafter, a detuning calibration method for stabilizing an alignment of lasing modes in an external cavity type tunable light source according to an embodiment of the present invention will be explained.

An external cavity type tunable light source according to an embodiment of the present invention may include a phase controller. In an external cavity type tunable light source, a wavelength may basically be determined by a filter structure having a narrow bandwidth. Therefore, stability of a lasing mode may be determined by where the lasing is made based on a peak value within a transmission bandwidth or reflection bandwidth of the filter.

Therefore, the phase controller may be implemented such that a wavelength of a lasing mode is located in a stable position within the transmission bandwidth or reflection bandwidth of the filter based on a phase control electrode. Positioning the wavelength of the lasing mode in a desired location within the transmission bandwidth or reflection bandwidth of the filter may be called detuning, which means moving the wavelength of the lasing mode to a longer wavelength or shorter wavelength from the maximum value of the reflection or transmission.

For example, the phase controller may be configured to change the refractive index or to subtly change the length of the laser, thus adjusting the position of the lasing mode so that the external cavity type tunable light source operates with stability as in FIG. 4(a).

FIG. 5 is a graph illustrating changes of characteristics that occur upon operation of a phase controller in an external cavity type tunable light source according to an embodiment of the present invention.

FIG. 5 illustrates measurement results of a wavelength and power of a lasing mode and their relationships with the spectral reflectivity of the external cavity filter in response to detuning the wavelength of the lasing mode using the phase controller. Such a graph may be called a detuning curve. This graph illustrates results of a total of three measurements: two operations of decreasing a phase controller input power from a high value to low value, and one operation of increasing a phase controller input power from a low value to a high value between the two operations of decreasing a phase controller input power.

For example, an external cavity type tunable light source according to an embodiment of the present invention may be configured based on a polymer material having a thermo-optical coefficient of approximately −0.3 nm/° C., and may include a phase controller.

The phase controller may, for example, be configured by forming a heater electrode in an optical waveguide part having no distributed Bragg grating. When a current is injected into the phase controller to generate heat, a subtle change will occur in the refractive index due to the thermo-optical effect, and this may cause a change in the phase of a subtle change in the entire length of the resonator of the external cavity laser.

Measurements on a first curve 500 in FIG. 5 are results of measuring a peak wavelength of a lasing mode, and measurements on a second curve 550 in FIG. 5 are results of measuring a peak power for each measured peak wavelength on the first curve 500.

The first curve 500 shows that as the phase controller input power gets lower, the lasing mode moves to a longer wavelength due to a negative thermo-optical coefficient. For example, a mode in the center of FIG. 4(a) has the most highest reflectivity, and thus it performs lasing, and in this state, when the input power of the phase controller is lowered, the mode moves to a longer wavelength until up to a point where the alignment of the modes changes as in FIG. 4(b), and after this point, the loss of an lasing mode gets bigger than the short wavelength mode of FIG. 4(b), thereby causing a mode hopping phenomenon to this mode.

On the contrary, when the input power of the phase controller gets higher, the lasing mode may move to a shorter wavelength. In this case, a situation opposite to the case of the input power of the phase controller getting lower occurs, and thus for the same reason, a hopping from a short wavelength mode to a longer wavelength mode occurs, which is repeated according to changes of power.

Meanwhile, also in the case where the input power of the phase controller has the same value, a bistable region may occur where two different modes occur according to the history of approaching to this value. In this case, a nonlinear gain phenomenon occurs by which the gains of the side modes are more suppressed and thus even when a mode alignment as in FIG. 4(b) occurs, a mode hopping does not occur directly but occurs after detuning is made further. Therefore, the stabilization region of the lasing mode itself increases. Another effect caused by the nonlinear gain phenomenon is a gain enhancement for the longer wavelength mode and a gain suppression for the shorter wavelength mode, and thus the overall detuning curve as a function of the reflectivity itself appears to have been moved to the longer wavelength side. Accordingly, FIG. 5 also shows that the center wavelength of the reflectivity curve as a function of the wavelength moved to a shorter wavelength in the entire range of measurements.

Referring the second curve 550, it can be seen that the optical power also changes according to the movement of the lasing mode. Herein, the optical power changes according to changes of reflectivity of an anti-reflection coated surface (r2 of FIG. 3) and changes in reflectivity loss. Measurements of FIG. 5 pertain to the output power being the smallest in the peak position of the reflectivity and the output power increasing as it moves from a longer wavelength to a shorter wavelength. Since the detuning region to a longer wavelength is larger, the peak output power appears at the end of the longer wavelength. Changes of an oscillating wavelength explained so far appears commonly in an external cavity type wavelength tunable light source, whereas the changes of an output power may show tendencies different from the aforementioned due to various factors such as internal loss of a gain medium and external cavity, and internal reflection inside the resonator etc.

However, since a same external cavity type tunable light source shows a same tendency with respect to changes in operation such as wavelength tuning, and thus based on the same tendency of the external cavity type tunable light source, it is possible to perform calibration after fabricating an external cavity type tunable light source so that the wavelength of the external cavity type tunable light source operating in an actual environment can be set stably.

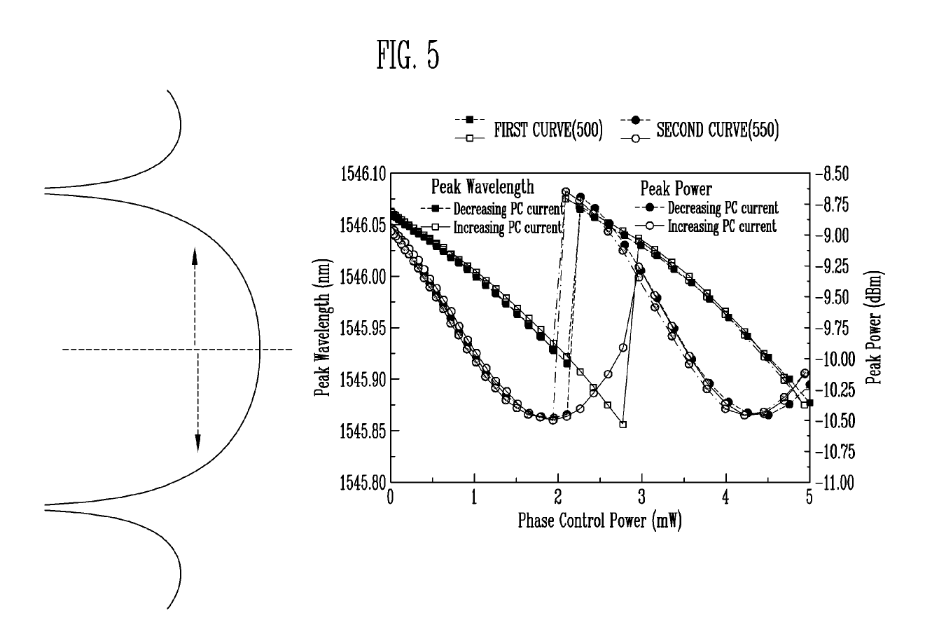

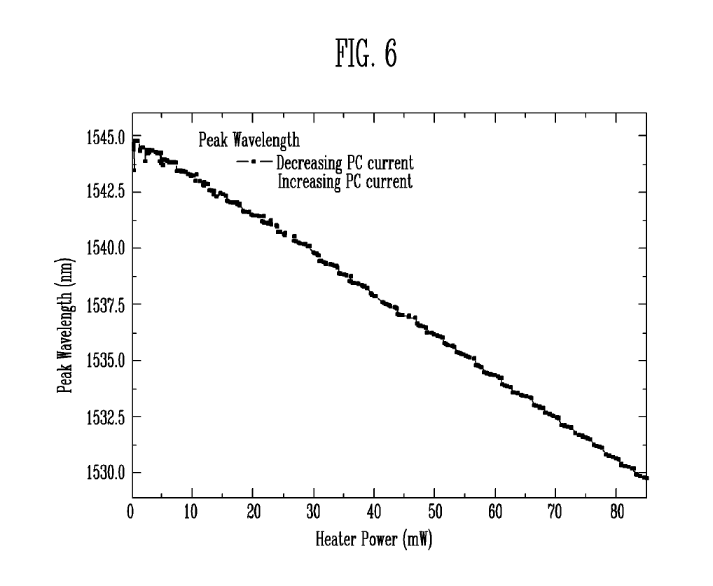

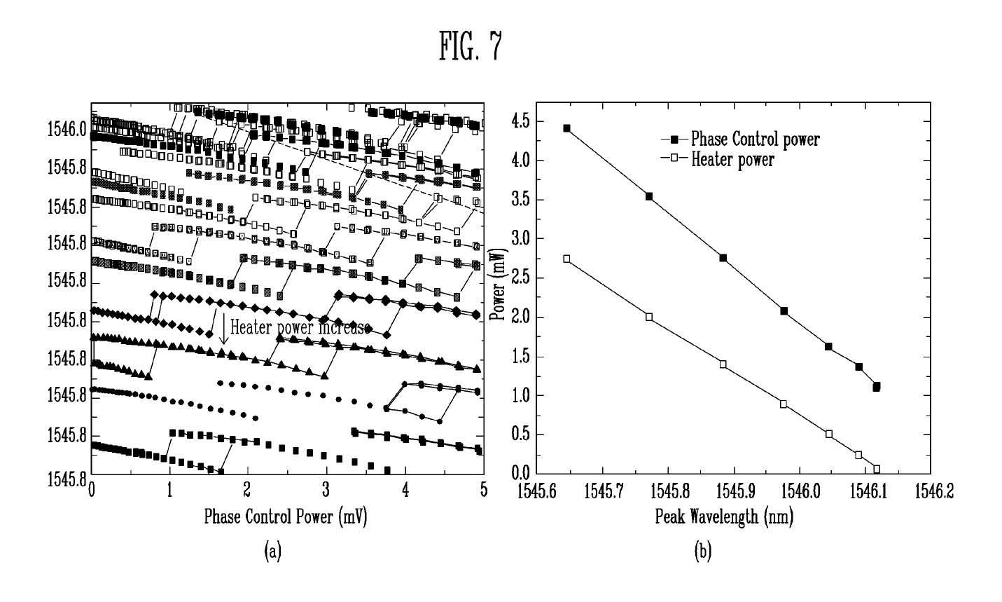

Hereinafter in FIGS. 6 to 8, a case of using an external cavity tunable light source in a field such as optical communication system will be explained.

FIG. 6 is a conceptual view illustrating a first calibration method of a method for setting operations of an external cavity type tunable light source according to an embodiment of the present invention.

In a first calibration, what is performed is an operation of adjusting only the heater power to find a tuning curve representing wavelength changes according to power. The red line is a result of measurements taken while actually changing the heater power, which is almost proportionate to the heater power. However, since a wavelength is found by adjusting only the heater power, each measurement has a different detuning condition, and thus the obtained value can be different from the wavelength of a simple formula obtained by calibration by as much as the distance of a mode at most.

FIG. 7 is conceptual views illustrating a method for setting operations of an external cavity type tunable light source according to an embodiment of the present invention.

FIG. 7 illustrates a method for obtaining detuning information at a second calibration step after fabricating an external cavity type tunable light source.

For example, a detuning curve may be obtained by setting a certain heater power value, and then varying a phase control power of the phase controller. It is also possible to vary the phase control power of the phase controller in other heat power values and obtain a different detuning curve. In this way, a detuning curve may be obtained near a desired wavelength.

After obtaining a detuning curve near a desired wavelength, a position where the lasing mode has a consistent detuning state is searched from each detuning curve based on the detuning curve.

The graph of FIG. 7(b) is an illustration of a same detuning position obtained in the aforementioned method, and the most convenient position for this is where a mode hopping would occur, and thus the graph illustrates the phase control power and heater power necessary when a longer wavelength mode hopping occurs.

Referring to FIG. 7(b), it can be seen that the curve of the phase control power and the curve of the heater power both move almost linearly. From the graph of FIG. 7(b), we may see the phase control power conditions and heater power conditions for obtaining information on the position where a long wavelength mode hopping occurs in the wavelength range of 1545.65 nm to 1546.12 nm. Of course, this curve does not have to linear. As long as the curve may be mathematized if only in a multiple equation, two variations, that is the phase control power and heater power may be adjustable by one control signal, thereby further simplifying the control of a tunable laser. Meanwhile, in order to use such a long wavelength mode hopping, the phase control power must be adjusted from a high value to a low value.

A method for storing information on the phase control power of the phase controller and the heater power in a position where a mode hopping occurs as a second calibration information of an external cavity tunable light source may be used for an additional adjustment reflecting the actual environment in an environment where the actual external cavity tunable light source is used. That is, a wavelength of a light source may have different values according to additional operational environment factors such as the external temperature and bias current, and thus even when the external cavity tunable light source performs a second calibration, tuning of a wavelength may not be made exactly.

Therefore, in actual use, an optical output may be generated in the external cavity tunable light source by performing an additional second calibration process. In the case of a tunable light source where a wavelength must be adjusted with precision, movement to a certain wavelength uses a wavelength locking apparatus. Therefore, it is possible to perform an operation of locking to a desired wavelength using the result of the second calibration that is a detuning operation for characteristics optimization. Herein, if only a wavelength can be directly measured in the process of the additional second calibration process, such an adjusting step is not that difficult. However, for a wavelength monitoring where a wavelength is directly measured, a high price optical spectrum measurement device must be provided.

Therefore, if a second calibration process is performed that is based on power measurement that requires only a low price monitor, such an adjustment process may be performed effectively at low cost.

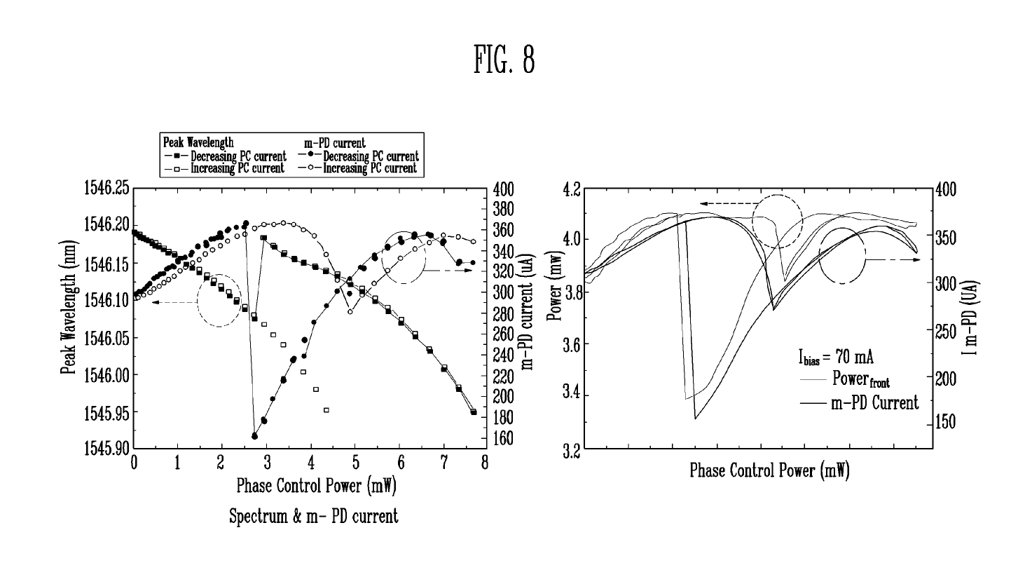

FIG. 8 are conceptual views illustrating a detuning method that is based on power monitoring according to an embodiment of the present invention.

FIG. 8 illustrates a method for performing a second calibration based on power monitoring after the first calibration. (a) of FIG. 8 shows wavelengths measured when varying the phase control power of the phase controller in an external cavity type tunable light source and currents of output lights that are generated through a high reflection coated surface of the rear surface of the gain medium using a monitoring PD; and (b) of FIG. 8 shows output powers generated through the external cavity measured when varying the phase control power of the phase controller in the external cavity type tunable light source and currents of output lights generated through the high reflection coated surface of the rear surface of the gain medium using the monitor PD.

The external cavity type tunable light source illustrated in FIG. 8 may have characteristics different from the external cavity type tunable light source illustrated in FIG. 7.

Power monitoring according to an embodiment of the present invention may be performed by monitoring the output power through the high reflection coated surface of the gain medium.

Referring to FIG. 8(a), one can see that the conditions for a mode hopping to occur obtained by measuring the spectrum may be obtained from the point where the power significantly changes by measuring the power. Therefore, an absolute wavelength position cannot be obtained based on the results of performing the power monitoring but the conditions may be confirmed, and thus it may be moved to a certain detuning position. Meanwhile, power monitoring may use both the output light generated through the external cavity and the output generated through the high reflection coated surface of the gain medium as in FIG. 8(b), but since the latter has relatively a much larger variation as in the drawing, monitoring may be much easier.

In the case of the external cavity tunable light source of FIG. 8, changes of power have a tendency in the opposite direction to the aforementioned result, but this is due to changes in internal characteristics as aforementioned (this is when the waveguide loss of the external cavity is great), and thus has the same tendency in the same element, causing no problem. Especially, it is more favorable since the variation range of the output light generated through the high reflectivity surface is larger.

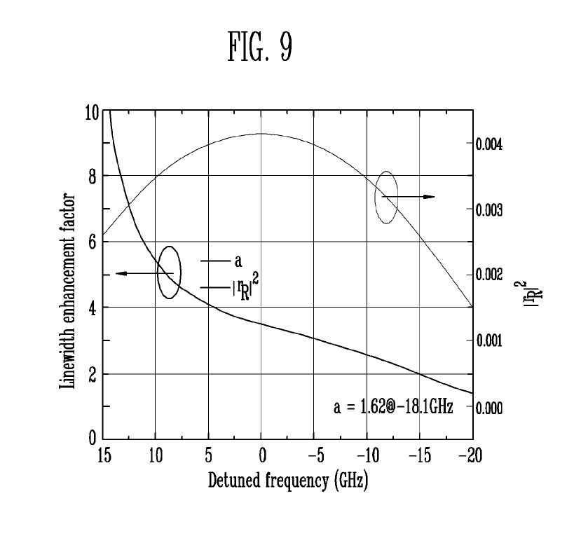

FIGS. 9 and 10 are graphs for explaining a detuning method according to an embodiment of the present invention.

Referring to FIG. 9, a line width improvement coefficient of the external cavity type tunable light source having reflectivity characteristics expressed as rR (the same as rR of FIG. 3) gets smaller as it gets closer to a longer wavelength. Since this is proportionate to wavelength chirping characteristics, one can see that the wavelength chirping characteristics would also get smaller as a detuning is performed with a longer wavelength.

Meanwhile, when an external cavity type tunable light source is directly modulated by a countersignal as in FIG. 10, a smaller detuning value may be obtained compared to the detuning range obtained from a nonmodulated curve. FIG. 10 illustrates detuning curves upon gradual increase of the size of the countersignal (Vpp in FIG. 10). One can see that as the size of the countersignal increases, the bistable region decreases. This is because the modes at the end terminals of long wavelengths and short wavelengths that used to be stable in CW (continuous wave) operations have gone beyond the stabilization range of the modes due to the chirping phenomenon caused by countersignal modulation.

Therefore, in such a case, a detuning range may be determined based on the detuning curve measured after the modulation by the countersignal.

However, when a modulation is not made in the light source as in light sources for coherent purposes, all of the bistable region may be used, and thus a detuning may be performed further towards the long wavelength, thereby obtaining a narrower linewidth.

Whether it is a countersignal modulation or continuous wave operation, in the actual operating conditions, a certain extent of offset will be applied in order to operate in a more stable region based on the point where a mode hopping occur.

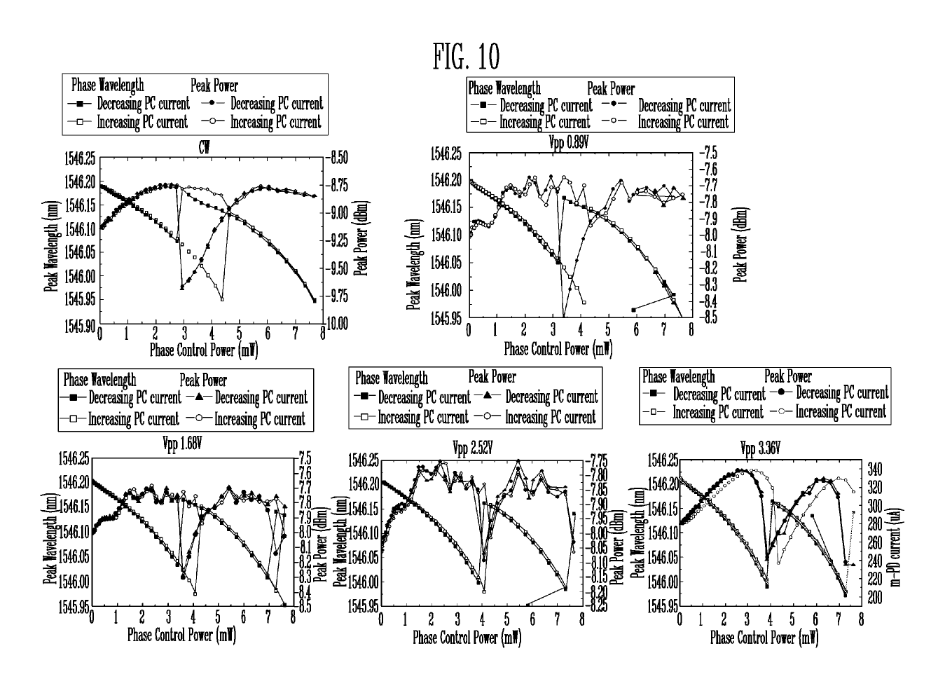

FIG. 11 is a view illustrating a method for performing a second calibration based on a detuning curve according to an embodiment of the present invention.

FIG. 11 illustrates a detuning occurring where a wavelength changes due to changes in external temperature even when the temperature of the element is kept constant.

Such changes appear due to changes in the external temperature, and thus changes in detuning that occur due to changes of the external temperature when an element is used for a long period of time may be obtained by performing a second calibration in the same method as aforementioned.

FIGS. 8 to 11 illustrate various examples of performing a second calibration in an external cavity type tunable light source. However, the second calibration may well be performed on an external cavity type tunable light source using other various methods as well.

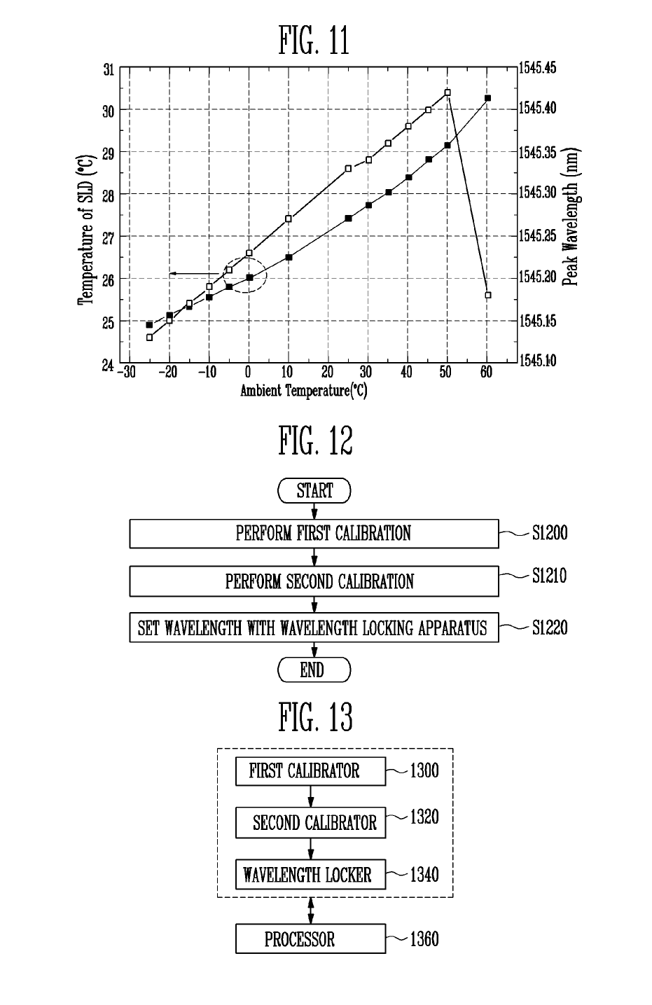

FIG. 12 is a flowchart illustrating a method for controlling operations of an external cavity type tunable light source according to an embodiment of the present invention.

Referring to FIG. 12, first of all, a first calibration of mathematizing a relationship between a heater power and a wavelength is performed by tuning the heater power only (S1200).

Then, a second calibration is performed (S1210).

At the step of performing the second calibration (S1210), it is possible to obtain calibration information necessary for performing the second calibration of the external cavity type tunable light source. For example, at the step of performing the second calibration, it is possible to obtain a detuning curve by varying a phase control power of the phase controller with the heater power fixed to a certain value. Furthermore, it is also possible to obtain other types of detuning curves by varying the phase control power of the phase controller under other wavelength conditions. When two or more curves are obtained by the aforementioned method, a straight line may be obtained as in FIG. 6(b), thus obtaining a second calibration curve near a desired wavelength. This way, it is possible to obtain a detuning curve so far as the tunable wavelength range, but in this case, other nonlinear effects will appear, and thus a mode hopping position obtained will not be in a straight line but in a curved shape.

Having obtained a detuning curve so far as the tunable wavelength range, based on this detuning curve, it is possible to obtain phase controller and heater power conditions for a position where a mode hopping occurs.

It is possible to store information on the phase control power and heater power of the phase controller at the position where a mode hopping occurs as second calibration information of the external cavity type tunable light source, and use the information for the second calibration of the external cavity type tunable light source. For example, this may be performed by monitoring a power through a high reflection coated surface of a gain medium.

Furthermore, an additional second calibration may be performed.

Even after the second calibration is performed, an additional second calibration may be performed during an actual operation of the external cavity type tunable light source. Herein, the second calibration may be performed based on other operation environments (for example, external temperature).

Then, a wavelength is set based on a wavelength locking apparatus (S1220).

At the step of setting a wavelength, by adjusting the wavelength using the wavelength locking apparatus, it is possible to find operating conditions showing desired characteristics at a desired wavelength.

FIG. 13 is a block diagram of an external cavity type tunable light source according to an embodiment of the present invention.

Referring to FIG. 13, the external cavity type tunable light source may include a first calibrator 1300, second calibrator 1320, wavelength locker 1340, and processor 1360.

The first calibrator 1300 may be configured to obtain a tuning curve as a function of a heater power so far as the tunable range. Herein, a curve is obtained by adjusting the heater power only.

The second calibrator 1320 may be configured to perform an additional adjustment on a wavelength after the first calibration is performed. The second calibrator 1320 may be configured to obtain a detuning curve so far as the tunable range, and then obtain information on the phase controller and heater power conditions regarding a position where a mode hopping occurs based on the detuning curve obtained. The second calibrator 1320 may be configured to perform an additional adjustment on the wavelength after monitoring a power through a high reflection coating surface of a gain medium. Alternatively, the second calibrator 1320 may perform an additional adjustment on the wavelength based on other operation environments (for example, external temperature).

The wavelength locker 1340 may be configured to adjust a wavelength based on a wavelength locking operation after calibration operations are performed by the first calibrator 1300 and second calibrator 1320.

The processor 1360 may be configured to control operations of the first calibrator 1300, second calibrator 1320, and wavelength locker 1340.

In the drawings and specification, there have been disclosed typical embodiments of the invention, and although specific terms are employed, they are used in a generic and descriptive sense only and not for purposes of limitation. As for the scope of the invention, it is to be set forth in the following claims. Therefore, it will be understood by those of ordinary skill in the art that various changes in form and details may be made therein without departing from the spirit and scope of the present invention as defined by the following claims.

What is claimed is:

1. A wavelength controlling method of an external cavity type tunable light source, the method comprising:
performing a first calibration of obtaining a tuning curve representing changes of a wavelength as a function of a heater power up to a wavelength range where the external cavity type tunable light source is tunable;
performing a second calibration of obtaining a detuning curve of the tunable wavelength range; and
setting a wavelength by performing a wavelength locking.

2. The method according to claim 1,
wherein the second calibration is performed based on phase control power information and heater power information regarding a position where a mode hopping occurs that were obtained based on the detuning curve.

3. The method according to claim 2,
wherein the second calibration is performed based on a result of a power monitoring, and
the power monitoring is performed by monitoring an output power through a high reflection coated surface of a gain medium.

4. The method according to claim 3,
wherein the power monitoring is performed by further monitoring the output power through the external cavity.

5. The method according to claim 2,
wherein the second calibration is performed based on information on an external temperature where the external cavity type tunable light source operates.

6. An external cavity type tunable light source apparatus comprising:
a first calibrator configured to perform a first calibration of obtaining a tuning curve representing changes of a wavelength as a function of a heater power up to a wavelength range where the external cavity type tunable light source is tunable;
a second calibrator configured to perform a second calibration of obtaining a detuning curve of the tunable wavelength range;
a wavelength locker configured to set a wavelength by performing a wavelength locking; and
a controller configured to control the first calibrator and the second calibrator to perform the first calibration and second calibration, respectively, of the external cavity type tunable light source apparatus, and to control the wavelength locker to set the wavelength.

7. The apparatus according to claim 6,
wherein the second calibrator performs the second calibration based on phase control power information and heater power information regarding a position where a mode hopping occurs that were obtained based on the detuning curve.

8. The apparatus according to claim 7,
wherein the second calibrator performs the second calibration based on a result of a power monitoring, and
the power monitoring is performed by monitoring an output power through a high reflection coated surface of a gain medium.

9. The apparatus according to claim 8,
wherein the power monitoring is performed by further monitoring the output power through the external cavity.

10. The apparatus according to claim 7,
wherein the second calibrator performs the second calibration based on information on an external temperature where the external cavity type tunable light source apparatus operates.
